(19) United States
(12) Patent Application Publication
(10) Pub. No.: US 2005/0201142 A1
(43) Pub. Date: Sep. 15, 2005

(54) Semiconductor integrated circuit device

(75) Inventor: Naoki Kuroda, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/072,298

(22) Filed: Mar. 7, 2005

(30) Foreign Application Priority Data
Mar. 11, 2004 (JP) 2004-069563

(51) Int. Cl. G11C 11/24

(52) U.S. Cl. 365/149

(57) ABSTRACT

A large capacity DRAM block, which is accessible by a logic circuit, includes a VBB/VPP power supply circuit. The other DRAM blocks accessible by a logic circuit share the VBB/VPP power supply circuit of the large capacity DRAM block as their VBB/VPP power supply circuit.

### CROSS-REFERENCE TO RELATED APPLICATION

The disclosure of Japanese Patent Application No. 2004-69563 filed on Mar. 11, 2004 including specification, drawings and claims is incorporated herein by reference in its entirety.

### BACKGROUND OF THE INVENTION

The present invention relates to a semiconductor integrated circuit device in which one or more logic circuits and a plurality of DRAM blocks accessed from those logic circuits are incorporated.

Conventionally, memories corresponding to individual logic circuit blocks have been embedded on a system LSI to achieve performance improvement and power consumption reduction. FIG. 3 is a block diagram illustrating an example of a conventional semiconductor integrated circuit device. As shown in FIG. 3, a static random access memory (which will be hereinafter referred to as a “SRAM”) 51 having a size ranging from about several kilobits to about several hundred kilobits is used as a storage section for data which is required to be processed at high speed. This is because SRAM has high random access performance and efficient compilability as well, such that capacity and bit width necessary for data processing can be combined easily. On the other hand, as a data storage section for large volume data which does not need high-speed processing and has certain limited patterns, a general dynamic random access memory (which will be hereinafter referred to as a “DRAM”) 52 having a size on the order of megabits or more is disposed (see non-patent literature 2, for example.)

Meanwhile, DRAMs which are different from general DRAMs have been embedded on an increasing number of system LSIs in order to achieve not only performance increase and power consumption reduction, but also total cost reduction or the like obtainable by optimizing necessary memory capacity to a certain degree (see non-patent literature 1, for example.)
(Non-patent literature 1) Hideo Ohwada and six other persons ‘A single-Chip Band-Segmented-Transmission OFDM Demodulator for Digital Terrestrial Television Broadcasting’ 2001 IEEE International Solid-State Circuits Conference
(Non-patent literature 2) Toshiba Semiconductor Company, ‘Embedded DRAM technology’ (the search of which was performed on Sep. 25, 2003) Internet <http://www.semicon.toshiba.co jp/prd/asic/index.html>

### SUMMARY OF THE INVENTION

However, the conventional device has the following problems.

In the configuration shown in FIG. 3, for each logic circuit block, one or more SRAMs suitable for a necessary memory space and a necessary number of bits are incorporated by utilizing the high compilability of the SRAMs. This permits local optimization of the memory allocation. However, since the capacity of each SRAM is small, even if the ratio of the total memories to the chip becomes too high, the designer of the system LSI is not likely to notice that. Consequently, memory optimization in the entire system LSI is not necessarily performed properly in many cases.

Furthermore, as the scale of system LSI has increased along with performance improvement thereof, the design of respective circuit blocks has been specialized and subdivided year after year. As a result, the ratio of embedded memories has been increasing, but memory optimization in the entire system LSI has become more difficult.

Moreover, SRAM, whose memory cells each consist of six transistors, is not suited for having a large capacity in terms of integration. Also, if the memory area of SRAM is increased for a larger capacity, high speed performance, which is an advantage of the SARM, deteriorates. These problems have also presented difficulties in achieving the optimization of the entire memories.

On the other hand, DRAM, whose memory cells each consist of, e.g., a transistor and a capacitor, is superior to SRAM in terms of high integration. Thus, incorporation of DRAM has also been examined and realized to attain the optimization of the entire memories.

However, DRAM that requires incorporation of a specific refresh circuit and a specific internal power supply circuit is smaller than SRAM in memory cell ratio. Thus, in cases where a plurality of DRAMs having a small capacity on the order of kilobits, for example, are incorporated, a problem occurs in that the area overhead increases. In view of this, most DRAMs incorporated in conventional system LSIs typically have a large capacity on the order of megabits. Therefore, it has been practically very difficult to incorporate DRAMs for the purpose of the optimization of memory allocation to respective logic circuit blocks.

In view of the above problems, an object of the present invention is to provide a semiconductor integrated circuit device in which a plurality of DRAM blocks are arranged without causing an increase in area overhead.

An inventive semiconductor integrated circuit device includes: one or more logic circuits; a first DRAM block including an internal power supply circuit and accessible by at least one of the logic circuits; and a second DRAM block smaller in capacity than the first DRAM block and accessible by at least one of the logic circuits, wherein whole or part of the internal power supply circuit of the first DARM block is shared as a power supply circuit for the second DRAM block.

In the inventive device, since the whole or part of the internal power supply circuit of the first DARM block is shared as a power supply circuit for the second DRAM block, the whole or part of the second internal power supply circuit can be omitted. Then, even if the plurality of DRAM blocks are disposed, increase in the area overhead is suppressed.

In the inventive device, the internal power supply circuit preferably includes: a reference circuit for generating a reference voltage serving as a reference for power supply voltage; a detection circuit for detecting variation in the power supply voltage based on the reference voltage; an oscillator circuit for outputting an oscillation signal in response to output from the detection circuit; and a charge pump circuit for supplying current in accordance with the oscillation signal to maintain the level of the power supply voltage. The reference circuit, the detection circuit, and the oscillator circuit are preferably shared by the second DRAM block.

In the inventive device, the internal power supply circuit preferably includes: a reference circuit for generating a reference voltage serving as a reference for power supply voltage; a detection circuit for detecting variation in the power supply voltage based on the reference voltage; an oscillator circuit for outputting an oscillation signal in response to output from the detection circuit; and a charge pump circuit for supplying current in accordance with the oscillation signal to maintain a level of the power supply voltage. The reference circuit is preferably shared by the second DRAM block.

The internal power supply circuit is preferably a VBB power supply circuit.

The internal power supply circuit is preferably a VPP power supply circuit.

The first DRAM block preferably has a capacity on the order of megabits. Also, the second DRAM block preferably has a capacity on the order of kilobits.

According to the present invention, a plurality of DARM blocks are arranged without increasing area overhead and decreasing the stability of power supply voltage, thereby facilitating the optimization of memory allocation and hence reducing the device costs further.

### BRIEF DESCRIPTION OF THE DRAWINGS

FIG. 1 is a block diagram illustrating a configuration for a semiconductor integrated circuit device in accordance with an embodiment of the present invention.

FIG. 2 is a block diagram illustrating another configuration for the semiconductor integrated circuit device in accordance with the embodiment of the present invention.

FIG. 3 illustrates an exemplary configuration of a conventional semiconductor integrated circuit device.

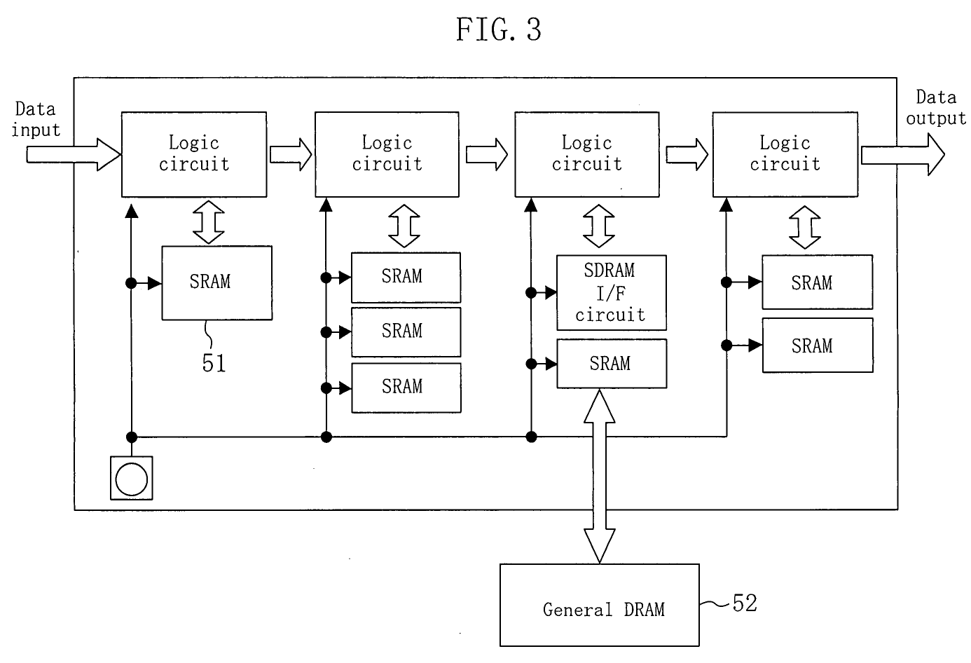

### DESCRIPTION OF THE PREFERRED EMBODIMENTS

Hereinafter, preferred embodiments of the present invention will be described with reference to the accompanying drawings.

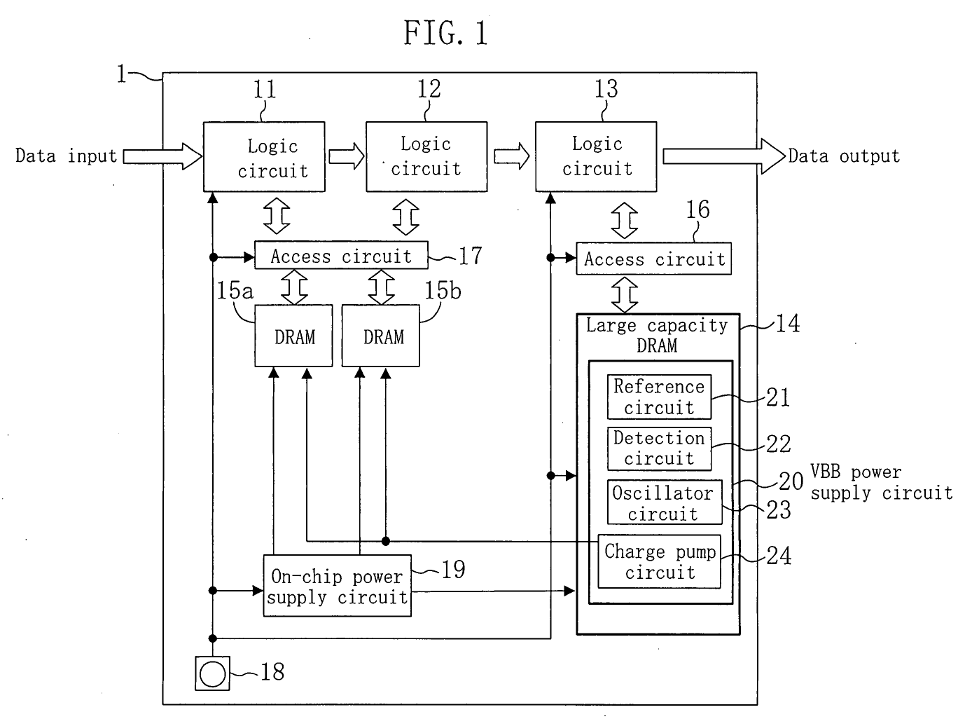

FIG. 1 is a block diagram illustrating the configuration of the main part of a semiconductor integrated circuit device in accordance with an embodiment of the present invention. In FIG. 1, the semiconductor integrated circuit device 1 includes a plurality of logic circuits 11, 12, and 13 for realizing respective predetermined processing functions, a large capacity DRAM block 14 serving as a first DRAM block, and DRAM blocks 15a and 15b being smaller in capacity than the large capacity DRAM block 14 and serving as second DRAM blocks. The large capacity DRAM block 14 is accessible by the logic circuit 13 via an access circuit 16. The DRAM blocks 15a and 15b are each accessible by both the logic circuits 11 and 12 via an access circuit 17. The access circuit 17 is designed to be capable of performing time division data processing so that the logic circuits 11 and 12 share the DRAM blocks 15a and 15b. The reference numeral 18 denotes an external power supply pad, while the reference numeral 19 represents an on-chip power supply circuit for lowering high voltage supplied to the external power supply pad 18 to generate supply voltage. Output from the on-chip power supply circuit 19 is supplied to each of the large capacity DRAM block 14 and DARM blocks 15a and 15b.

The large capacity DRAM block 14 includes a VBB power supply circuit 20 serving as an internal power supply circuit. The VBB power, which is substrate bias power used for substrate voltage for access transistors in memory cells in the DRAM, is minus power. The VBB power supply circuit 20 performs voltage comparison based on a reference circuit 21 for generating a reference voltage serving as a reference for VBB voltage and the reference voltage generated by the reference circuit 21. The VBB power supply circuit 20 includes a detection circuit 22 for detecting variation in the VBB voltage, an oscillator circuit 23 for outputting an oscillation signal in response to output from the detection circuit 22, and a charge pump circuit 24 for supplying current in accordance with the oscillation signal output from the oscillator circuit 23 to maintain the VBB voltage level.

In the configuration shown in FIG. 1, output from the charge pump circuit 24 in the VBB power supply circuit 20 of the large capacity DRAM block 14 is also supplied as the VBB power to the other DRAM blocks 15a and 15b. That is, the VBB power supply circuit 20 of the large capacity DRAM block 14 is shared as the VBB power supply circuit for the DRAM blocks 15a and 15b.

The large capacity DRAM block 14 has a capacity on the order of megabits. The capacity on the order of megabits is a capacity of 1 megabit or more but less than 1 gigabit, for example, a capacity of from about several ten megabits to about several hundred megabits, such as 16 megabits, 64 megabits, or 128 megabits. The capacity of the DRAM blocks 15a and 15b, which share the internal power supply circuit, is on the order of kilobits. The capacity on the order of kilobits is a capacity of 1 kilobit or more but less than 1 megabit, for example, a capacity of from about several ten kilobits to about several hundred kilobits, such as 16 kilobits or 128 kilobits. It should be noted that the respective capacities of the DRAM blocks are not limited to those described herein.

Current flowing through the VBB power supply when the DRAMs are operating is extremely small as compared with VDD power or the like for effecting the operation of the DRAMs. Therefore, there is not very much change in the VBB voltage except when the power is turned on. In addition, the large capacity DRAM on the order of megabits such as 16 megabits or 64 megabits, in particular, has a large memory cell area, allowing the DRAM to have a large substrate capacitance for storing the VBB voltage. The large substrate capacitance, which is equal to or grater than several nF, acts as a smoothing capacitance, so that even if small current flows through the VBB power supply, the VBB power level is stable.

Therefore, even if the VBB power supply circuit 20 in the large capacity DRAM block 14 is shared as a VBB power supply for the other small capacity DRAM blocks 15a and 15b as in the configuration of FIG. 1, a stable VBB voltage level is maintained. In this case, as compared with a configuration in which a VBB power supply circuit is separately provided for the DRAM blocks 15a and 15b, the layout area can be reduced by an area taken by the power supply circuit otherwise needed, while power consumption by the power supply circuit can also be decreased. In other words, it is possible to reduce the size and power consumption of the device without decreasing the stability of the VBB power supply voltage.

Although in the configuration shown in FIG. 1 the VBB power supply circuit 20 of the large capacity DRAM block 14 is entirely shared as the VBB power supply circuit for the DRAM blocks 15a and 15b, part of the VBB power supply circuit 20 may be shared. For instance, all of the circuits except for the charge pump circuit 24, that is, the reference circuit 21, the detection circuit 22, and the oscillator circuit 23 may be shared and only a charge pump circuit may be separately provided for each of the DRAM blocks 15a and 15b or a common charge pump circuit may be provided for the DRAM blocks 15a and 15b.

Also, switching devices or separation means in interconnect layers may be provided in VBB power supply lines going from the VBB power supply circuit 20 to the respective DRAM blocks 15a and 15b. If there is a sufficient margin in the data retention characteristics of the DRAM blocks 15a and 15b, for example, the DRAM blocks 15a and 15b are disconnected from the VBB power supply circuit 20 so that a reference voltage is supplied from a VSS power supply. This reduces power consumption by the VBB power supply circuit 20, while avoiding the effects of variation in the VBB voltage upon the large capacity DRAM block 14.

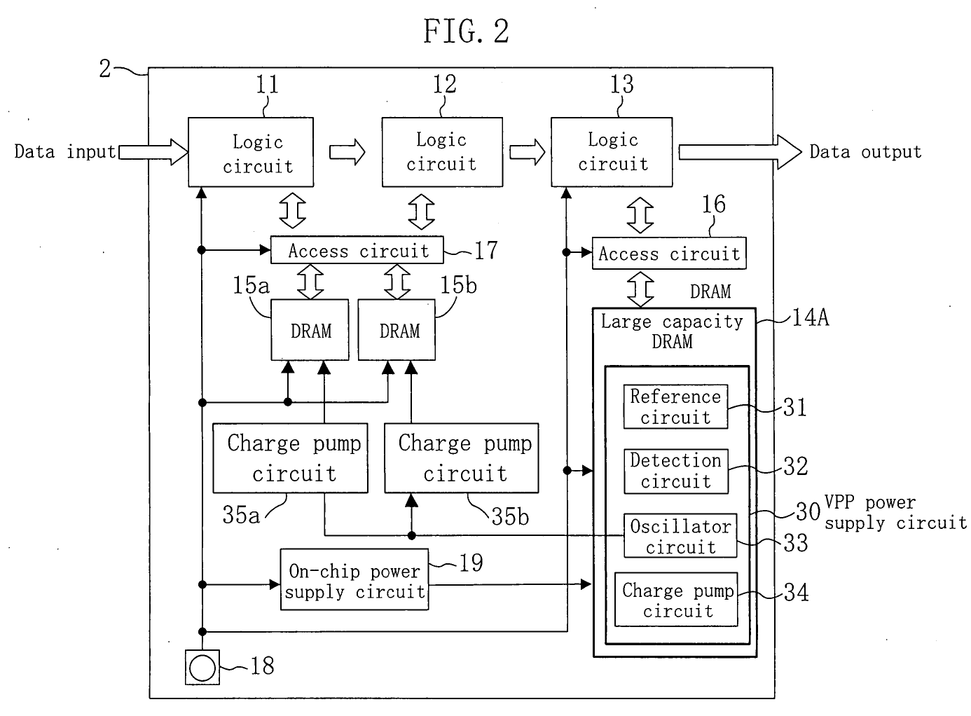

FIG. 2 is a block diagram illustrating the configuration of the main part of another exemplary semiconductor integrated circuit device in accordance with the embodiment of the present invention. In FIG. 2, the same members as those shown in FIG. 1 are identified by the same reference numerals. The semiconductor integrated circuit device 2 includes a plurality of logic circuits 11, 12, and 13 for realizing respective predetermined processing functions, a large capacity DRAM block 14A serving as a first DRAM block, and DRAM blocks 15a and 15b being smaller in capacity than the large capacity DRAM block 14A and serving as second DRAM blocks. The large capacity DRAM block 14A is accessible by the logic circuit 13 via an access circuit 16. The DRAM blocks 15a and 15b are each accessible by both the logic circuits 11 and 12 via an access circuit 17. The access circuit 17 is designed to be capable of performing time division data processing so that the logic circuits 11 and 12 share the DRAM blocks 15a and 15b. The reference numeral 18 denotes an external power supply pad, while the reference numeral 19 represents an on-chip power supply circuit for lowering high voltage supplied to the external power supply pad 18 to generate supply voltage. Output from the on-chip power supply circuit 19 is supplied only to the large capacity DRAM block 14A for the reduction of power consumption.

The large capacity DRAM block 14A has a VPP power supply circuit 30 serving as an internal power supply circuit. The VPP power is internal booster power and is used for, e.g., word line power for controlling memory cells in the DARM. The VPP power supply circuit 30 performs voltage comparison based on a reference circuit 31 for generating a reference voltage serving as a reference for VPP voltage and the reference voltage generated by the reference circuit 31. The VPP power supply circuit 30 includes a detection circuit 32 for detecting variation in the VPP voltage, an oscillator circuit 33 for outputting an oscillation signal in response to output from the detection circuit 32, and a charge pump circuit 34 for supplying current in accordance with the oscillation signal output from the oscillator circuit 33 to maintain the VPP voltage level.

Charge pump circuits 35a and 35b are also provided for VPP power supply to the respective DRAM blocks 15a and 15b. The charge pump circuits 35a and 35b receive an oscillation signal output from the oscillator circuit 33 within the VPP power supply circuit 30 and supply current to the respective DRAM blocks 15a and 15b. More specifically, some members of the VPP power supply circuit 30 of the large capacity DRAM block 14A, that is, the reference circuit 31, the detection circuit 32, and the oscillator circuit 33 are shared as a VPP power supply circuit for the DRAM blocks 15a and 15b.

Booster power such as the VPP power requires a large amount of current consumption. Therefore, as shown in FIG. 2, the configuration, in which only the charge pump circuits 35a and 35b for supplying current are provided separately and all of the circuit blocks in the VPP power supply circuit 30 except for the charge pump circuit are shared, is effective in terms of current supply capability and chip area reduction. In the configuration shown in FIG. 2, the charge pump circuits 35a and 35b are provided for the DRAM blocks 15a and 15b, respectively. However, a single charge pump circuit may be provided for a common use by the DRAM blocks 15a and 15b. In other words, a charge pump circuit(s) may be arranged suitably in accordance with current consumption by the respective DRAM blocks.

Another configuration, in which only the reference circuit 31 is shared and all of the circuits except for the reference circuit are separately provided, may also be employed. More specifically, only the reference voltage may be used in common, while current supply and detection of variation in the VPP voltage may be performed separately. Such a configuration permits current to be supplied in accordance with a local phenomenon, such as an increase in the frequency of activation or a decrease in the VPP voltage, and is thus effective in terms of stable operation of the DRAMs. In that configuration, if a shielding structure, such as that employed for the power lines, is adopted for output signal lines of the reference circuit, the reference signal which is very sensitive to signal variation or the like is stabilized.

Alternatively, all of the circuit blocks in the VPP power supply circuit 30 may be shared.

In the forgoing description, an example of the internal power supply circuit in the DRAM is the VBB power supply circuit or the VPP power supply circuit. However, the present invention may be realized in the same manner in other cases where the internal power supply circuit is a ½ VDD power supply circuit or the like serving as a bit line precharge power source or a memory cell plate power source. Nevertheless, a ½ VDD power supply circuit is small in circuit size, and some memory systems do no need any internal power supply circuit. Therefore, there may be cases where it is effective to separately dispose internal power supply circuits for the respective DRAMs.

It should be noted that in the configurations shown in FIGS. 1 and 2 the on-chip power supply circuit 19 may be omitted, so that the power is directly supplied to the respective DRAMs from the external power supply pad 18.

Also, the capacities of the DRAM blocks are not limited to those described in this embodiment and the number of logic circuits and the number of DRAMs are not limited to those described herein.

The present invention, which allows a plurality of DRAM blocks to be arranged without increasing area overhead and decreasing the stability of power supply voltage, is effective in achieving performance improvement and cost reduction obtainable by reducing the chip area of a system LSI, for example.

1. A semiconductor integrated circuit device comprising:
one or more logic circuits;
a first DRAM block including an internal power supply circuit and accessible by at least one of the logic circuits; and
a second DRAM block smaller in capacity than the first DRAM block and accessible by at least one of the logic circuits,
wherein whole or part of the internal power supply circuit of the first DARM block is shared as a power supply circuit for the second DRAM block.

2. The device of claim 1, wherein the internal power supply circuit includes:
a reference circuit for generating a reference voltage serving as a reference for power supply voltage;
a detection circuit for detecting variation in the power supply voltage based on the reference voltage;
an oscillator circuit for outputting an oscillation signal in response to output from the detection circuit; and
a charge pump circuit for supplying current in accordance with the oscillation signal to maintain a level of the power supply voltage,
wherein the reference circuit, the detection circuit, and the oscillator circuit are shared by the second DRAM block.

3. The device of claim 1, wherein the internal power supply circuit includes:
a reference circuit for generating a reference voltage serving as a reference for power supply voltage;
a detection circuit for detecting variation in the power supply voltage based on the reference voltage;
an oscillator circuit for outputting an oscillation signal in response to output from the detection circuit; and
a charge pump circuit for supplying current in accordance with the oscillation signal to maintain a level of the power supply voltage,
wherein the reference circuit is shared by the second DRAM block.

4. The device of claim 1, wherein the internal power supply circuit is a VBB power supply circuit.

5. The device of claim 1, wherein the internal power supply circuit is a VPP power supply circuit.

6. The device of claim 1, wherein the first DRAM block has a capacity on the order of megabits.

7. The device of claim 6, wherein the second DRAM block has a capacity on the order of kilobits.
